(19) United States
(12) Patent Application Publication
(10) Pub. No.: US 2026/0342348 A1
(43) Pub. Date: Oct. 29, 2026

(54) CALIBRATION METHOD FOR NONLINEAR ANALOG TO DIGITAL CONVERSION CIRCUIT, AND REFERENCE VOLTAGE GENERATING CIRCUIT THEREOF

(71) Applicant: GALAXYCORE SHANGHAI LIMITED CORPORATION, Shanghai (CN)

(72) Inventors: Lixin ZHAO, Shanghai (CN); Minlan LI, Shanghai (CN); Jingxuan QIAO, Shanghai (CN)

(73) Assignee: GALAXYCORE SHANGHAI LIMITED CORPORATION, Shanghai (CN)

(21) Appl. No.: 19/115,211

(22) PCT Filed: Jul. 19, 2023
(86) PCT No.: PCT/CN2023/108170

§ 371 Date: Mar. 25, 2025

(30) Foreign Application Priority Data
Sep. 30, 2022 (CN) 202211207493.7

(51) Int. Cl. H03M 1/10; H04N 25/70

(52) U.S. Cl. CPC H03M 1/1009; H04N 25/70

(57) ABSTRACT

A calibration method for a nonlinear analog-to-digital conversion circuit of an image sensor, and a reference voltage generating circuit thereof are provided. Prior to or during normal operation of the nonlinear analog-to-digital conversion circuit of the image sensor, the nonlinear analog-to-digital conversion circuit of the image sensor is used to test multiple reference voltages generated by the reference voltage generating circuit to obtain calibration parameters of the nonlinear analog-to-digital conversion circuit of the image sensor that are used to calibrate an output value of the nonlinear analog-to-digital conversion circuit of the image sensor at normal operation. In this manner, changes in nonlinear ADC calibration parameters caused by changes in working environment and working parameters are updated in real time, thereby improving stability and precision of the nonlinear analog-to-digital conversion circuit of the image sensor.

### CROSS-REFERENCE TO RELATED APPLICATIONS

This application is a National Stage of International Application No. PCT/CN2023/108170 filed on Jul. 19, 2023, which claims priority to Chinese Patent Application No. 202211207493.7, filed on Sep. 30, 2022, and entitled “CALIBRATION METHOD FOR NONLINEAR ANALOG-TO-DIGITAL CONVERSION CIRCUIT, AND REFERENCE VOLTAGE GENERATING CIRCUIT THEREOF”, the entire disclosure of which is incorporated herein by reference.

### TECHNICAL FIELD

The present disclosure generally relates to a calibration method for a nonlinear analog-to-digital conversion circuit of an image sensor, and a reference voltage generating circuit thereof.

### BACKGROUND

An analog-to-digital converter, also known as an A/D converter, or ADC for short, generally refers to an electronic component that converts analog signals into digital signals. The A/D converter has been widely used in industry, medical care, communications and other fields to meet the needs of various data acquisition applications.

In image sensors, as a size of pixel unit arrays continues to expand, traditional Chip Level Analog to Digital Converters can no longer meet requirements of high frame rates, thus, high-frame-rate image sensors usually adopt column-level A/D converters. The column-level A/D converters can achieve high precision with only a small size and low power consumption, and are widely used in high-pixel and high-frame-rate image sensors.

The A/D converter mainly consists of a comparator and a storage unit or a counting unit, and requires a ramp (VRAMP) signal as a comparison level of the comparator. Precision of the ramp signal directly affects output precision of the ADC. In addition, application scenarios of high-frame rate image sensors require corresponding high-speed ramp signals, thus, how to generate high-speed and high-precision ramp signals is an essential research topic.

Traditionally, the ramp signals are linear. It requires a longer time or a higher speed to achieve the same effective precision, or the effective precision that can be achieved is lower at the same speed and time.

Photon shot noise exists in all image sensors, and increases as an input signal increases. However, quantization noise of ADC does not change with the input signal. Therefore, when the input signal is relatively large, the photon shot noise will dominate. In this condition, performance of the A/D converter is higher than required, and precision can be reduced. The performance on the ramp signal is that a slope for large signals is greater than a slope for small signals. In this manner, for the same effective output precision, a conversion time of ADC may be shortened and a frame rate may be increased, or for the same frame rate, the effective output precision of ADC may be improved. Therefore, a nonlinear ADC with a multi-slope nonlinear ramp signal can better adapt to high-speed and high-precision applications of image sensors.

### SUMMARY

Embodiment of the present disclosure provide a calibration method for a nonlinear analog-to-digital conversion circuit of an image sensor, and a reference voltage generating circuit thereof, so as to update changes in nonlinear ADC calibration parameters caused by changes in working environment and working parameters in real time to improve stability and precision of a nonlinear ADC.

In one aspect, an embodiment of the present disclosure provides a calibration method for a nonlinear analog-to-digital conversion circuit of an image sensor, including: providing the nonlinear analog-to-digital conversion circuit of the image sensor; providing a reference voltage generating circuit; and prior to or during normal operation of the nonlinear analog-to-digital conversion circuit of the image sensor, using the nonlinear analog-to-digital conversion circuit of the image sensor to test multiple reference voltages generated by the reference voltage generating circuit to obtain calibration parameters of the nonlinear analog-to-digital conversion circuit of the image sensor, wherein the calibration parameters are used to calibrate an output value of the nonlinear analog-to-digital conversion circuit of the image sensor at normal operation, to improve stability and precision of the nonlinear analog-to-digital conversion circuit of the image sensor.

Optionally, the reference voltage generating circuit includes at least one calibration row with drive disposed inside or outside a pixel array of the image sensor, and a voltage source or a current source disposed outside the pixel array, wherein each of the at least one calibration row with drive includes a resistor or capacitor module including resistors or capacitors connected in series, and a first terminal and a second terminal of the resistor or capacitor module are respectively connected to the voltage source or the current source outside the pixel array.

Optionally, said using the nonlinear analog-to-digital conversion circuit of the image sensor to test the multiple reference voltages generated by the reference voltage generating circuit includes: in response to one calibration row with drive being selected, the voltage source or the current source providing multiple reference voltages before driving through the resistor or capacitor module; after being driven by the calibration row with drive, the nonlinear analog-to-digital conversion circuit of the image sensor performing analog-to-digital conversion on the multiple reference voltages after driving simultaneously; removing an offset error introduced in the calibration row with drive by a driving circuit and the nonlinear analog-to-digital conversion circuit of the image sensor using a correlated double sampling method; and obtaining the calibration parameters of the nonlinear analog-to-digital conversion circuit of the image sensor after a test.

Optionally, each of the at least one calibration row with drive further includes a plurality of calibration row units, each of the plurality of calibration row units at least includes the driving circuit and a row selection circuit, the driving circuit is a source follower transistor or a unit gain driving circuit, and the row selection circuit is a row selection transistor or a row selection switch circuit.

Optionally, a metal line is used to connect the plurality of calibration row units and serves as the resistors connected in series in the calibration row with drive, a first terminal of the metal line is connected to the voltage source, a second terminal of the metal line is connected to the current source, the voltage source generates a first reference voltage before driving, and a current controlled by the current source flows through the metal line to generate multiple subsequent reference voltages before driving.

Optionally, in the calibration row with drive, gates of source follower transistors in a same row are connected to a first metal line, gates of the row selection transistors in the same row are connected to a same row control line, a first terminal of the first metal line is connected to the voltage source, and the second terminal of the first metal line is connected to the current source through a first selection switch; wherein the voltage source generates the first reference voltage before driving, the current controlled by the current source flows through the first metal line to generate the multiple subsequent reference voltages before driving, the multiple subsequent reference voltages before driving are the same as the first reference voltage when the first selection switch is turned off, and the multiple subsequent reference voltages before driving are different from the first reference voltage when the first selection switch is turned on. After being driven by the calibration row with drive, the reference voltages after driving required for the correlated double sampling are obtained.

Optionally, the gates of the source follower transistors are connected to the first metal line at equal intervals to make the different reference voltages before driving are voltages that change at equal intervals.

Optionally, each of the at least one calibration row with drive further includes a second metal line connected in parallel with the first metal line, a first terminal of the second metal line is connected to the voltage source, and a second terminal of the second metal line is connected to the current source through a second selection switch, wherein the second selection switch is turned on when the first selection switch is turned off, and the second selection switch is turned off when the first selection switch is turned on, to make loads of the voltage source be consistent with loads of the current source.

Optionally, the at least one calibration row with drive includes a plurality of calibration rows with drive, and a first arrangement and a second arrangement are alternately adopted in the plurality of calibration rows with drive, wherein in the first arrangement, a first terminal of the first and second metal lines is disposed at a left terminal of the calibration row with drive, and a second terminal of the first and second metal lines is disposed at a right terminal of the calibration row with drive; and in the second arrangement, the first terminal of the first and second metal lines is disposed at the right terminal of the calibration row with drive, and the second terminal of the first and second metal lines is disposed at the left terminal of the calibration row with drive.

Optionally, in one of the at least one calibration row with drive, a plurality of selection switch groups are respectively arranged at a first terminal of the first and second metal lines, at a second terminal of the first and second metal lines, and between the first metal line and the second metal line, and an on-off state of the plurality of selection switch groups is controlled to achieve an alternation between following two connection states: a left terminal of the calibration row with drive being connected to the voltage source and the right terminal of the calibration row with drive being connected to the current source; or the right terminal of the calibration row with drive being connected to the voltage source and the left terminal of the calibration row with drive being connected to the current source.

Optionally, the calibration parameters are refreshed periodically every frame or multiple frames; or the calibration parameters are refreshed in response to working environment or working parameters changing to a preset threshold.

Optionally, the at least one calibration row with drive includes a plurality of calibration rows with drive, and digital codes corresponding to the reference voltages after driving output from a same column of the plurality of calibration rows with drive are averaged to form a nonlinear output curve.

Optionally, a reference voltage range after driving output from the at least one calibration row with drive is adjusted by adjusting a current of the current source.

Optionally, the at least one calibration row with drive includes a plurality of calibration rows with drive, and the plurality of calibration rows with drive are connected with one another as a whole to provide the reference voltages before driving and output the reference voltages after driving.

In another aspect, an embodiment of the present disclosure provides a reference voltage generating circuit for calibrating a nonlinear analog-to-digital conversion circuit of an image sensor, including: at least one calibration row with drive disposed inside or outside a pixel array of the image sensor, and a voltage source or a current source disposed outside the pixel array, wherein each of the at least one calibration row with drive includes a resistor or capacitor module including resistors or capacitors connected in series, and a first terminal and a second terminal of the resistor or capacitor module are respectively connected to the voltage source or the current source outside the pixel array; wherein in response to one calibration row with drive being selected, the voltage source or the current source provides multiple reference voltages before driving through the resistor or capacitor module; after being driven by the calibration row with drive, the nonlinear analog-to-digital conversion circuit of the image sensor performs analog-to-digital conversion on the multiple reference voltages after driving simultaneously; an offset error introduced in the calibration row with drive by a driving circuit and the nonlinear analog-to-digital conversion circuit of the image sensor is removed using a correlated double sampling method; and calibration parameters of the nonlinear analog-to-digital conversion circuit of the image sensor are obtained after a test.

Optionally, each of the at least one calibration row with drive further includes a plurality of calibration row units, each of the plurality of calibration row units at least includes the driving circuit and a row selection circuit, the driving circuit is a source follower transistor or a unit gain driving circuit, and the row selection circuit is a row selection transistor or a row selection switch circuit.

Optionally, a metal line is used to connect the plurality of calibration row units and serves as the resistors connected in series in the calibration row with drive, a first terminal of the metal line is connected to the voltage source, a second terminal of the metal line is connected to the current source, the voltage source generates a first reference voltage before driving, and a current controlled by the current source flows through the metal line to generate multiple subsequent reference voltages before driving.

Optionally, in the calibration row with drive, gates of source follower transistors in a same row are connected to a first metal line, gates of the row selection transistors in the same row are connected to a same row control line, a first terminal of the first metal line is connected to the voltage source, and the second terminal of the first metal line is connected to the current source through a first selection switch.

Optionally, the gates of the source follower transistors are connected to the first metal line at equal intervals.

Optionally, each of the at least one calibration row with drive further includes a second metal line connected in parallel with the first metal line, a first terminal of the second metal line is connected to the voltage source, and a second terminal of the second metal line is connected to the current source through a second selection switch.

Optionally, the at least one calibration row with drive includes a plurality of calibration rows with drive, and a first arrangement and a second arrangement are alternately adopted in the plurality of calibration rows with drive, wherein in the first arrangement, a first terminal of the first and second metal lines is disposed at a left terminal of the calibration row with drive, and a second terminal of the first and second metal lines is disposed at a right terminal of the calibration row with drive; and in the second arrangement, the first terminal of the first and second metal lines is disposed at the right terminal of the calibration row with drive, and the second terminal of the first and second metal lines is disposed at the left terminal of the calibration row with drive.

Optionally, in one of the at least one calibration row with drive, a plurality of selection switch groups are respectively arranged at a first terminal of the first and second metal lines, at a second terminal of the first and second metal lines, and between the first metal line and the second metal line, and an on-off state of the plurality of selection switch groups is controlled to achieve an alternation between following two connection states: a left terminal of the calibration row with drive being connected to the voltage source and the right terminal of the calibration row with drive being connected to the current source; or the right terminal of the calibration row with drive being connected to the voltage source and the left terminal of the calibration row with drive being connected to the current source.

Optionally, the at least one calibration row with drive includes a plurality of calibration rows with drive which are connected to the same current source.

Optionally, the at least one calibration row with drive includes a plurality of calibration rows with drive which are connected with one another as a whole.

Optionally, the at least one calibration row with drive includes a plurality of calibration rows with drive which are connected to the same voltage source.

Compared with existing techniques, in the calibration method for the nonlinear analog-to-digital conversion circuit of the image sensor, and the reference voltage generating circuit thereof provided in the embodiments of the present disclosure, prior to or during normal operation of the nonlinear analog-to-digital conversion circuit of the image sensor, the nonlinear analog-to-digital conversion circuit of the image sensor is used to test multiple reference voltages generated by the reference voltage generating circuit to obtain calibration parameters of the nonlinear analog-to-digital conversion circuit of the image sensor that are used to calibrate an output value of the nonlinear analog-to-digital conversion circuit of the image sensor at normal operation. In this manner, changes in nonlinear ADC calibration parameters caused by changes in working environment and working parameters are updated in real time, thereby improving stability and precision of the nonlinear analog-to-digital conversion circuit of the image sensor.

### BRIEF DESCRIPTION OF THE DRAWINGS

Other features, objects and advantages of this disclosure will become more clear from following detailed description of non-limiting embodiments with reference to accompanying drawings.

FIG. 1 is a structural diagram of an image sensor adopting a calibration method for a nonlinear analog-to-digital conversion circuit of the image sensor according to the present disclosure;

FIG. 2 is a circuit diagram of an ordinary row pixel unit;

FIG. 3 is a schematic diagram of a reference voltage generating circuit according to an embodiment of the present disclosure;

FIG. 4 is a schematic diagram of a voltage source according to an embodiment;

FIG. 5 is a schematic diagram of a current source according to an embodiment;

FIG. 6 is a timing diagram of control signals according to the embodiment as shown in FIG. 3;

FIG. 7 is a schematic diagram of a reference voltage generating circuit according to an embodiment of the present disclosure;

FIG. 8 is a timing diagram of control signals according to the embodiment as shown in FIG. 7;

FIG. 9 is a schematic diagram of a reference voltage generating circuit according to an embodiment of the present disclosure;

FIG. 10 is a timing diagram of control signals according to the embodiment as shown in FIG. 9; and

FIG. 11 is a schematic diagram of a reference voltage generating circuit according to an embodiment of the present disclosure.

In the drawings, the same or similar reference numerals denote the same or similar devices (modules) or steps throughout different drawings.

### DETAILED DESCRIPTION

In order to solve the problems in existing techniques, embodiments of this disclosure provide a calibration method for a nonlinear analog-to-digital conversion circuit of an image sensor, and a reference voltage generating circuit thereof.

In following specific description of preferred embodiments, reference will be made to accompanying drawings which constitute a part of this disclosure. The accompanying drawings show by way of example specific embodiments that can implement this disclosure. The illustrative embodiments are not intended to be exhaustive in enumerating all embodiments of this disclosure. It could be understood that other embodiments may be utilized, and structural or logical modifications may also be made without departing from the scope of this disclosure. Therefore, the following specific description is not restrictive, and the scope of this disclosure is limited by appended claims.

In one aspect, an embodiment of the present disclosure provides a calibration method for a nonlinear analog-to-digital conversion circuit of an image sensor, including: providing the nonlinear analog-to-digital conversion circuit of the image sensor; providing a reference voltage generating circuit; and prior to or during normal operation of the nonlinear analog-to-digital conversion circuit of the image sensor, using the nonlinear analog-to-digital conversion circuit of the image sensor to test multiple reference voltages generated by the reference voltage generating circuit to obtain calibration parameters of the nonlinear analog-to-digital conversion circuit of the image sensor, wherein the calibration parameters are used to calibrate an output value of the nonlinear analog-to-digital conversion circuit of the image sensor at normal operation, to improve stability and precision of the nonlinear analog-to-digital conversion circuit of the image sensor.

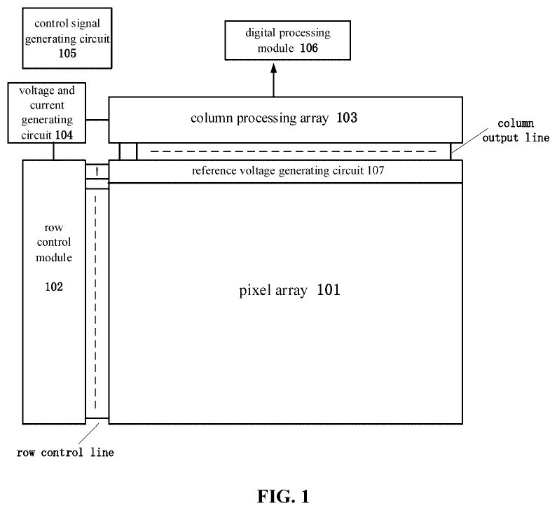

FIG. 1 is a structural diagram of an image sensor adopting a calibration method for a nonlinear analog-to-digital conversion circuit of the image sensor according to the present disclosure. The image sensor includes a pixel array 101, a row control module 102, a column processing array 103, a voltage and current generating circuit 104, a control signal generating circuit 105, and a digital processing module 106, and also includes a reference voltage generating circuit 107 for calibrating the nonlinear ADC of the image sensor.

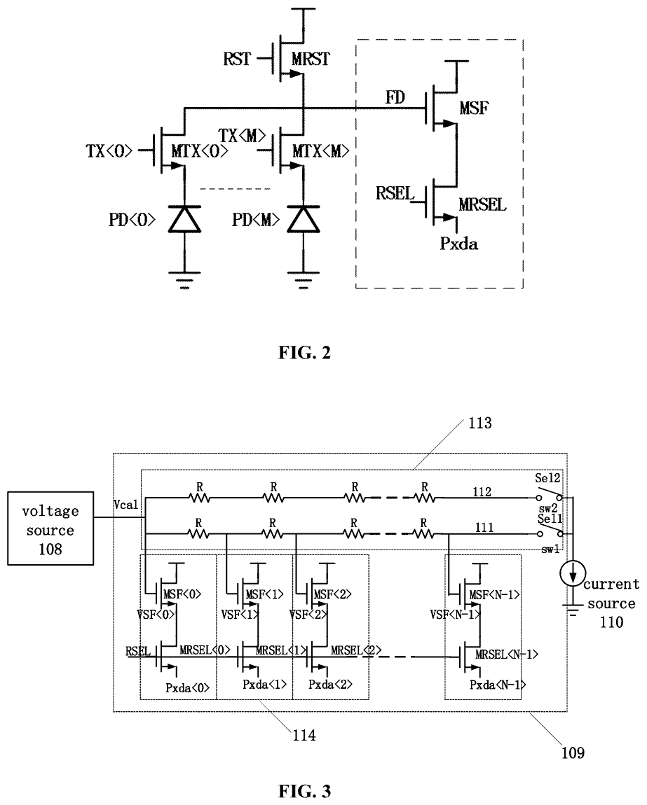

The pixel array 101 includes a plurality of ordinary row pixel units, and a circuit diagram of a single pixel unit (the structure is not limited thereto, but only for the convenience of explanation) is illustrated in FIG. 2. The pixel unit has an ordinary pixel unit structure, specifically including a reset transistor MRST, transfer transistors MTX<0> to MTX<M> (where M is an integer greater than or equal to 0), photosensitive units PD<0> to PD<M> corresponding to the transfer transistors in one-to-one correspondence, a source follower transistor MSF, and a row selection transistor MRSEL.

The voltage and current generating circuit 104 is configured to provide voltage and current to the row control module 102 and the column processing array 103, and includes a ramp signal generating circuit (not shown). Compared with a traditional ramp signal generating circuit, a ramp signal output by the ramp signal generating circuit in the embodiment is nonlinear so as to improve a frame rate and precision of the image sensor. Therefore, an ADC (not shown) in the column processing array 103 may be considered as a nonlinear analog-to-digital conversion circuit. An implementation method of the nonlinear ramp signal generating circuit has been mentioned in other patent applications of the applicant, and the column processing array has an architecture similar as a conventional column-level ADC in an image sensor, which are not repeated here.

The reference voltage generating circuit 107 is not limited, as long as it can generate multiple reference voltage signals. An output range of these reference voltage signals can reach a full scale of the nonlinear ADC (that is, a signal output range of the pixel array of the image sensor). Prior to or during normal operation of the nonlinear ADC, these reference voltages are provided to the nonlinear ADC in the column processing array 103 for analog-to-digital conversion to obtain an input-output conversion curve of the nonlinear ADC. The digital processing module 106 calculates calibration parameters of the nonlinear ADC based on the conversion curve, where the calibration parameters are used to calibrate an output of the ADC when the image sensor operates normally.

The calibration method for the nonlinear analog-to-digital conversion circuit of the image sensor provided in the present disclosure can work periodically as needed, and update changes of the calibration parameters of the nonlinear ADC caused by changes of working environment or parameter settings of the image sensor in real time, thereby improving stability and precision of the nonlinear analog-to-digital conversion circuit, so as to achieve excellent image sensor performance.

A structure and working principle of the reference voltage generating circuit 107 are described in detail below in conjunction with specific embodiments.

FIG. 3 is a schematic diagram of a reference voltage generating circuit applicable for a calibration method for a nonlinear analog-to-digital conversion circuit of an image sensor according to an embodiment of the present disclosure. In some embodiments, the reference voltage generating circuit includes at least one calibration row 109 with drive, as well as a voltage source 108 and a current source 110. The voltage source 108 and the current source 110 are disposed outside the pixel array 101. The at least one calibration row 109 with drive may be disposed inside the pixel array 101 or outside the pixel array 101, and may include one calibration row or multiple calibration rows, which can be specifically configured as needed. As an example, a circuit structure of one calibration row is illustrated in a dotted box 109, which includes a resistor module 113 consisting of multiple resistors connected in series. Those skilled in the art could understand that the resistor module may be replaced by a capacitor module consisting of multiple capacitors connected in series. A first terminal and a second terminal of the resistor or capacitor module are respectively connected to the voltage source 108 or the current source 110. Here, for an example, the first terminal of the resistor module 113 is connected to the voltage source 108, and the second terminal of the resistor module 113 is connected to the current source 110. Alternatively, in an embodiment not shown, the first and second terminals of the resistor or capacitor module may be connected to different voltage sources, respectively, or the first and second terminals of the resistor or capacitor module may be connected to different current sources, respectively.

In some embodiments, in response to one calibration row 109 with drive being selected, the voltage source 108 or the current source 110 provides multiple reference voltages before driving through the resistor or capacitor module 113. After being driven by the calibration row with drive, the nonlinear analog-to-digital conversion circuit of the image sensor performs analog-to-digital conversion on the multiple reference voltages after driving simultaneously. Afterward, an offset error introduced in the calibration row with drive by a driving circuit and the nonlinear analog-to-digital conversion circuit of the image sensor is removed using a correlated double sampling method. The calibration parameters of the nonlinear analog-to-digital conversion circuit of the image sensor are obtained after a test.

Each calibration row 109 with drive further includes a plurality of calibration row units 114 each of which at least includes the driving circuit and a row selection circuit. The driving circuit is a source follower transistor or a unit gain driving circuit, and the row selection circuit is a row selection transistor or a row selection switch circuit. In the embodiment, the driving circuit is a source follower transistor MSF, and the row selection circuit is a row selection transistor MRSEL. A number of columns of the calibration row units in the reference voltage generating circuit 107 is the same as a number of columns of ordinary row pixel units in the pixel array 101. Outputs of each column of the pixel array 101 and outputs of each column of the reference voltage generating circuit 107 are connected together correspondingly to be pxda<0> to pxda<N−1>, respectively, where N is the number of columns of the pixel units in the image sensor.

Preferably, a metal line may be used to connect the plurality of calibration row units 114 and serves as the resistor module 113 including the resistors connected in series in the calibration row 109 with drive, a first terminal of the metal line is connected to the voltage source 108, and a second terminal of the metal line is connected to the current source 110. The voltage source 108 generates a first reference voltage before driving, and a current controlled by the current source 110 flows through the metal line to generate multiple subsequent reference voltages before driving. Using a metal line as the resistors connected in series can be implemented in a single pitch, and has some advantages such as small integral error, high linearity, high precision (above 11 bits), etc.

Specifically, the resistor module 113 includes a first metal line 111 and a second metal line 112 connected in parallel. A first terminal (a left terminal in FIG. 3) of the first metal line 111 is connected to an output Vcal of the voltage source 108, and a second terminal (a right terminal in FIG. 3) of the first metal line 111 is connected to the current source 110 through a first selection switch sw1. Similarly, a first terminal (a left terminal in FIG. 3) of the second metal line 112 is connected to the output Vcal of the voltage source 108, and a second terminal (a right terminal in FIG. 3) of the second metal line 112 is connected to the current source 110 through a second selection switch sw2. A plurality of resistors R connected in series are arranged on the first metal line 111 and the second metal line 112, which can be resistors of the metal lines themself or external resistors. Preferably, each resistor R is a metal resistor with equal resistance, which is equivalent to dividing resistance on the metal line into (N−1) equal parts, where N is the number of the columns of the pixel units in the image sensor. When R is the resistor of the metal line itself, the resistance of one resistor R corresponds to resistance of the metal line corresponding to one pixel unit. Therefore, a current flowing through the resistors on the metal line can achieve uniform voltage changes on the resistors on the metal line. Afterward, voltage output points are set at equal intervals on the metal line as the reference voltages before driving, and are respectively connected to gates of the source follower transistors MSF in the calibration row 109 with drive. After being driven by the source follower transistors MSF, reference voltages after driving are generated and provided to the nonlinear ADC for quantization, to obtain a linear-input and nonlinear-output curve of the nonlinear ADC. A digital module obtains the calibration parameters of the nonlinear ADC of the image sensor based on the curve that are used to calibrate an output value of the nonlinear ADC of ordinary pixel units.

In the calibration row 109 with drive, the gates of the source follower transistors MSF in a same row are connected to the first metal line 111. Preferably, the gates of the source follower transistors MSF are connected to the first metal line 111 at equal intervals to divide the resistance of the first metal line 111, to make different reference voltages before driving are voltages that change at equal intervals. Gates of row selection transistors MRSEL in a same row are connected to a same row control line, and a control signal RSEL comes from the row control module 102 in FIG. 1. Compared with an ordinary pixel array 101, the reference voltage generating circuit 107 is the same in operation and signal processing except an input signal source. A controllable gate voltage of the source follower transistors of the reference voltage generating circuit 107 is used to simulate an entire signal output range of real pixel photosensitive units.

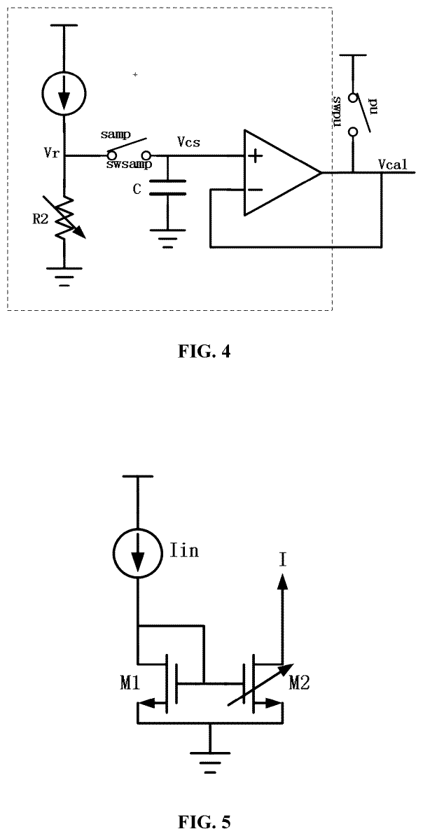

The voltage source 108 may be a simple voltage source or a complex voltage source generating circuit. FIG. 4 is merely a schematic diagram of the voltage source generating circuit according to an embodiment. A working process of the voltage source generating circuit is as following. A current of the current source flows through a variable resistor R2 to generate an output voltage Vr, a sampling circuit samples the voltage Vr to a capacitor C, and then the output voltage Vcal is obtained through a unit gain negative feedback circuit. Alternatively, a circuit in a dotted box in FIG. 4 may be closed, and a pull-up transistor swpu is turned on to pull the output voltage Vcal to a power supply voltage. The circuit is relatively common, and is not described in detail here.

The current source 110 may be a simple current source or a complex current source generating circuit. FIG. 5 is merely a schematic diagram of the current source generating circuit according to an embodiment. Its input current Iin comes from a nonlinear ramp signal generating circuit, which is a current related to a current source unit in the nonlinear ramp signal generating circuit. In this manner, the reference voltage generating circuit follows changes in the current of the current source unit in the nonlinear ramp signal generating circuit in real time, so as to better match a range of the nonlinear ADC. A transistor M2 is adjustable to match a situation where a gain is simulated by using output resistance of the nonlinear ramp signal generating circuit, and an amplitude of an output voltage of the nonlinear ramp signal changes. The embodiment shown in FIG. 5 is relatively simple, but a practical circuit may be more complicated.

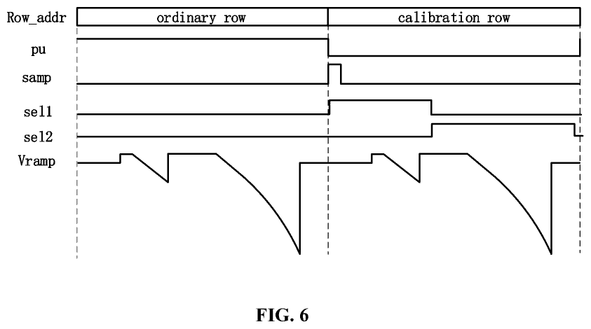

A working principle of the calibration method for the nonlinear ADC is described in detail below in conjunction with the structural diagram in FIG. 3 and a timing diagram in FIG. 6.

In response to the row control module 102 selecting an ordinary row in the pixel array 101, the reference voltage generating circuit 107 does not operate. The control signal RSEL of the row selection transistor MRSEL in the reference voltage generating circuit 107 is at a low level, and the row selection transistor MRSEL is in an off state. To save power consumption, a dotted box portion of the voltage source 108 and the current source 110 may be closed. A control signal pu is at a high level, and the pull-up transistor swpu in FIG. 4 is turned on to pull the output voltage Vcal to the power supply voltage. Control signals sel1 and sel2 of selection switches sw1 and sw2 connected with the right terminals of the two metal lines are both at a low level, and thus are turned off. The left terminals of the first metal line 111 and the second metal line 112 are connected to the power supply voltage, and the right terminals of the first metal line 111 and the second metal line 112 are in a suspended state. As no current flows through the metal lines 111 and 112, there is no voltage drop, thereby making a gate voltage of the source follower transistors MSF in the reference voltage generating circuit 107 fixed to the power supply voltage, i.e., simulating a state when the pixel units are not selected to prevent affecting normal operation of the pixel units.

In response to the row control module 102 selecting the calibration row 109 with drive in the reference voltage generating circuit 107, the dotted box portion of the voltage source 108 and the current source 110 are open, and at the same time, the control signal pu becomes low, and the pull-up transistor swpu is turned off, thus, the output voltage Vcal is determined by the dotted box portion in FIG. 4. The left terminals of the first metal line 111 and the second metal line 112 are always connected to the output voltage Vcal. The control signal sel2 of the second selection switch sw2 connected to the right terminal of the second metal line 112 is at a high level, thus, the switch sw2 is turned on to connect the right terminal of the second metal line 112 to the current source 110. The control signal sel1 of the first selection switch sw1 connected to the right terminal of the first metal line 111 is at a low level, thus, the switch sw1 is turned off to make the right terminal of the first metal line 111 in a suspended state. In this condition, the reference voltages before driving obtained on the gates of the source follower transistors MSF in the calibration row 109 with drive meet a following equation,

V_{SF}<0>=V_{SF}<1>=V_{SF}<2>= . . . =V_{SF}<N−1>=Vcal.

From above, when the first selection switch sw1 is turned off, the multiple subsequent reference voltages V_{SF}<0>, V_{SF}<1> . . . V_{SF}<N−1> before driving are the same as the first reference voltage Vcal, and the same reference voltage Vcal is used to simulate a reference signal voltage output by the pixel array of the image sensor. After being driven by the calibration row 109 with drive, the nonlinear analog-to-digital conversion circuit of the image sensor performs analog-to-digital conversion on the multiple reference voltages after driving simultaneously to obtain a digital output code corresponding to a reference signal of each column.

After the analog-to-digital conversion of the reference signals is completed, the control signal sel2 of the second selection switch sw2 connected to the right terminal of the second metal line 112 becomes low, the switch sw2 is turned off, and the right terminal of the second metal line 112 is in a suspended state. The control signal sel1 of the first selection switch sw1 connected to the right terminal of the first metal line 111 becomes high, the switch sw1 is turned on, and the right terminal of the first metal line 111 is connected to the current source 110. In this condition, as there is a current flowing through the first metal line 111, a voltage drop from left to right is generated, which is evenly applied to the gates of the source follower transistors MSF of the calibration row 109 with drive. The reference voltages on the gates of the source follower transistors MSF before driving meet a following equation,

V_{SF}<0>=Vcal

V_{SF}<1>=Vcal−I*R

V_{SF}<2>=Vcal−2*I*R

. . .

V_{SF}<N−1>=Vcal−(N−1)*I*R,

where I is an output current value of the current source, and R is equivalent metal resistance between the gates of two adjacent source follower transistors MSF on the first metal line.

From above, when the first selection switch sw1 is turned on, the multiple subsequent reference voltages V_{SF}<0>, V_{SF}<1> . . . V_{SF}<N−1> before driving are different from the first reference voltage Vcal. These different reference voltages Vcal to Vcal−(N−1)*I*R are used to simulate an image signal voltage output by the pixel array of the image sensor. After being driven by the calibration row 109 with drive, the nonlinear analog-to-digital conversion circuit of the image sensor performs analog-to-digital conversion on the multiple reference voltages after driving simultaneously to obtain a digital output code corresponding to an image signal of each column.

The offset error introduced in the calibration row with drive by the driving circuit and the nonlinear analog-to-digital conversion circuit of the image sensor is removed using the correlated double sampling method. From left to right, the reference voltages before driving vary from 0 to (N−1)*I*R linearly at intervals of I*R. Accordingly, the reference voltages after driving by the source follower transistors MSF vary from 0 to (N−1)*I*R*A, where A is a gain of the source follower transistors MSF. The range of the reference voltages after driving output by the calibration row 109 with drive can be adjusted by adjusting a magnitude of the current I of the current source 110, so as to match a voltage output range of the entire image signal of the image sensor. As the ADC is nonlinear, a digital output of the reference voltage generating circuit also varies nonlinearly from left to right, and accordingly a linear-input and nonlinear-output curve from left to right can be obtained. The digital module may use the curve as a reference to calculate the calibration parameters of the nonlinear ADC, and linearly straighten an output of the ordinary row pixel units to obtain an image with high precision.

It can be seen that if the calibration row 109 includes merely one first metal line 111, the circuit can also operate normally. Why the extra second metal line 112 is provided is explained below. If the second metal line 112 is not provided in the calibration row 109, when the calibration row 109 with drive is selected, as the source follower transistors MSF in all columns need to obtain the same reference voltage before driving to simulate the reference signal, the control signal of the first selection switch sw1 of the current source at the right terminal of the first metal line 111 must be at a low level to make the right terminal of the first metal line 111 in a suspended state, and no current flows through the first metal line 111. However, after the analog-to-digital conversion of the reference signal is completed, to generate a linearly varying voltage difference from left to right, the control signal of the first selection switch sw1 needs to be changed to a high level, and then the analog-to-digital conversion of the image signal is performed. In this condition, a current flows through the first metal line 111. This causes output loads of the voltage source 108 to be inconsistent and the output voltage Vcal to change during two times of quantization, resulting in a deviation between an initial value (a maximum voltage) of the image signal simulated by the calibration row with drive and the reference signal, and missing of a bottom segment signal, which is not conducive to the calibration of the digital module. In addition, a load current of the current source 110 is also different during the two times of quantization, and the current change requires time. If a stabilization time is not enough, calibration precision may be affected. When the second metal line 112 with the same resistance as the first metal line 111 is provided to be connected in parallel with the first metal line 111, the output loads of the voltage source 108 and the current source 110 are consistent during an entire row time, the output voltage Vcal and the output current I are relatively stable, the bottom segment signal will not be lost, and the effective reference voltage after driving can start from 0. There is no deviation between a starting value (maximum voltage) of the image signal simulated by the calibration row with drive and the reference signal, which is conducive to the digital module to calculate reasonable nonlinear calibration parameters and obtain images with high quality.

For a small-scale pixel array, when there are multiple calibration rows 109 with drive in the reference voltage generating circuit 107, the settings of each calibration row 109 can be completely the same as illustrated in the embodiment of FIG. 3.

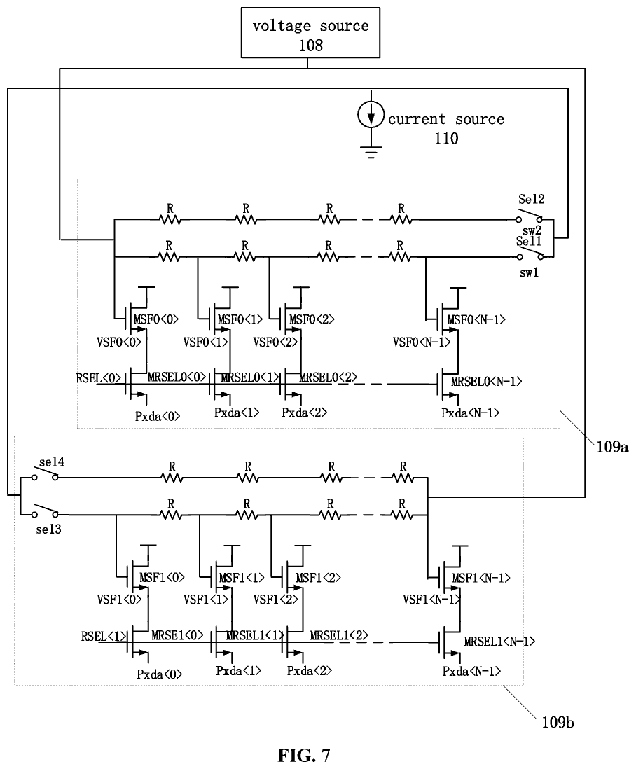

For a large-scale pixel array, due to left-right differences in signal drive, power supply systems, etc., there may be left-right differences in signal processing of the image sensor. To avoid influence of the left-right differences on the nonlinear ADC calibration, the calibration rows may be configured in two different directions, as shown in FIG. 7. Compared with FIG. 3, the reference voltage generating circuit 107 in this embodiment includes two calibration rows 109a and 109b with drive each of which has the same structure. Differences between the two calibration rows 109a and 109b with drive lie in that a left terminal of the upper row 109a is connected to the voltage source 108, and a right terminal of the upper row 109a is connected to the selection switch and the current source 110, while a right terminal of the lower row 109b is connected to the voltage source 108, and a left terminal of the lower row 109b is connected to the selection switch and the current source 110.

That is, when there are a plurality of calibration rows with drive in the reference voltage generating circuit 107, a first arrangement and a second arrangement are alternately adopted in the plurality of calibration rows with drive. In the first arrangement, a first terminal (one terminal for connecting to the voltage source) of the first and second metal lines is disposed at a left terminal of the calibration row with drive, and a second terminal (one terminal for connecting to the current source) of the first and second metal lines is disposed at a right terminal of the calibration row with drive; and in the second arrangement, the first terminal (one terminal for connecting to the voltage source) of the first and second metal lines is disposed at the right terminal of the calibration row with drive, and the second terminal (one terminal for connecting to the current source) of the first and second metal lines is disposed at the left terminal of the calibration row with drive.

FIG. 8 is a timing diagram of control signals according to the embodiment as shown in FIG. 7. When the upper row 109a is selected, the reference voltage after driving used to simulate the output of the pixel unit gradually increases from left to right, corresponding to the calibration row<0> with drive in FIG. 8. When the lower row 109b is selected, the reference voltage after drive used to simulate the output of the pixel unit gradually increases from right to left, corresponding to the calibration row<1> with drive in FIG. 8. A working principle and process are similar with the above embodiment as shown in FIG. 3 to FIG. 6, and are not repeated here. Two conversion curves from left to right and from right to left are obtained respectively based on the above method, which contain information about left-right differences. After digital processing on the two conversion curves, influence of the left-right differences on nonlinear ADC calibration can be eliminated.

From FIG. 7, although the reference voltage generating circuit 107 includes at least two calibration rows with drive, merely one voltage source 108 and one current source 110 are used, that is, multiple calibration rows with drive can be connected to the same voltage source or the same current source. On one hand, power consumption is saved, and on the other hand, the multiple calibration rows with drive can obtain the same input signal to avoid calibration deviation caused by inconsistent input signal slopes.

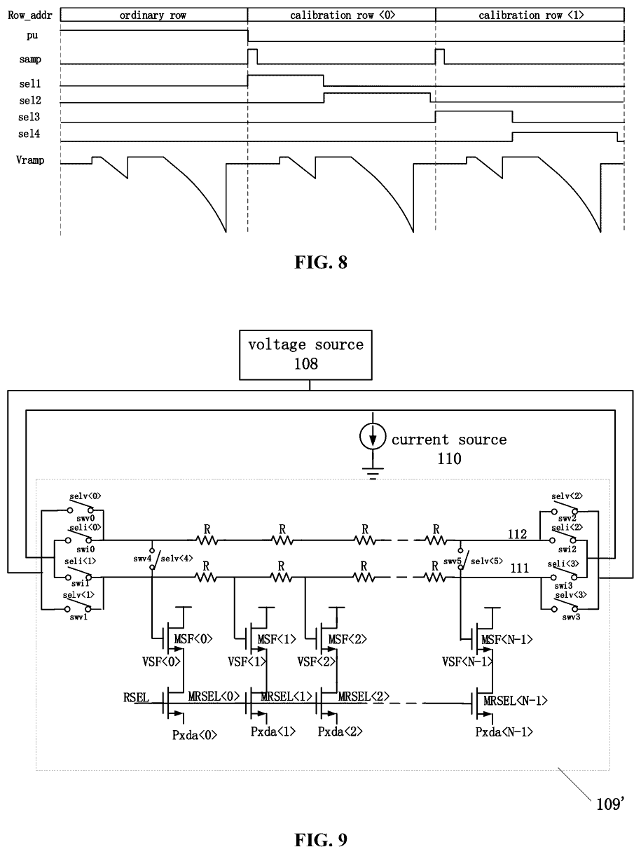

FIG. 9 illustrates another embodiment of eliminating left-right differences. Compared with FIG. 7, in FIG. 9, the left-right differences are eliminated without adding an additional calibration row with drive, but more switches are required and the control is more complicated.

In the embodiment, in addition to the voltage source 108, the current source 110, the first metal line 111, the second metal line 112, and the calibration row unit 114, the reference voltage generating circuit 107 further includes two voltage source selection switches swv0 and swv1, two current source selection switches swi0 and swi1, and a metal line short-circuit switch swv4 on the left, and two voltage source selection switches swv2 and swv3, two current source selection switches swi2 and swi3, and a metal line short-circuit switch swv5 on the right.

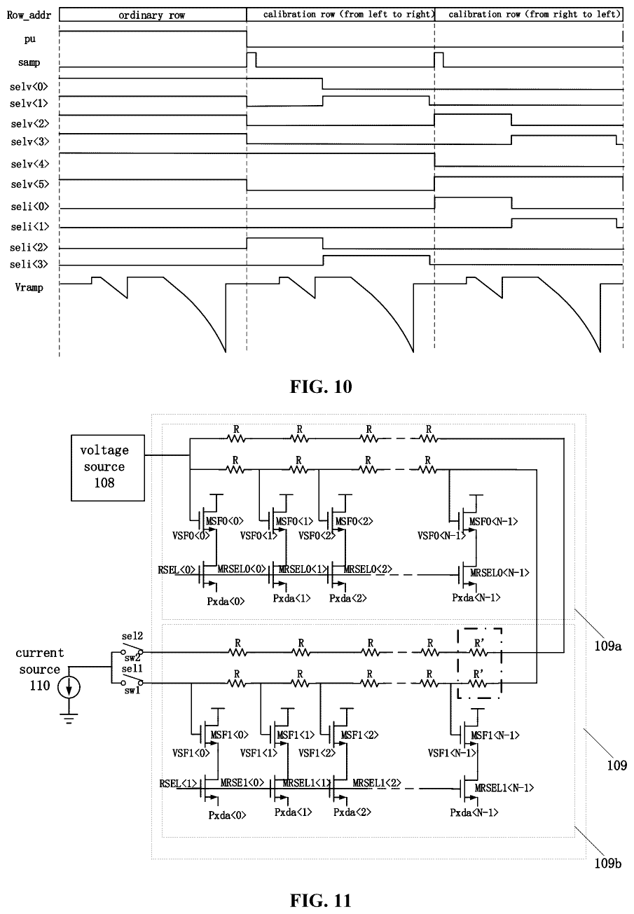

A circuit working principle of this embodiment is described in detail below in conjunction with the structural diagram of FIG. 9 and the timing diagram of FIG. 10.

When the row control module 102 selects an ordinary row in the pixel array 101, as in FIG. 3, a dotted box of the voltage source 108 and the current source 110 are closed, and the voltage source generating circuit is pulled to the power supply voltage by the pull-up switch swpu to save power consumption. In FIG. 9, the control selv<0> to selv<5> of the voltage selection switches swv0 to swv3, and the metal line short-circuit switches swv4 and swv5 are all at a high level, and the switches are turned on. The control signals seli<0> to seli<1> of the current selection switches swi<0> to swi<1> are all at a low level, and the switches are turned off. Gate voltages of the source follower transistors MSF in the calibration row 109′ with drive are all pulled to the power supply voltage.

When the row control module 102 selects the calibration row 109′ with drive in the reference voltage generating circuit 107, the pull-up switch swpu is turned off, and the dotted box portion of the voltage source 108 and the current source 110 are open.

First, the reference voltages after driving can be selected to change from left to right, requiring that the left terminal of the calibration row 109′ with drive is connected to the voltage source 108 through switches, and the right terminal of the calibration row 109′ with drive is connected to the current source 110 through switches. At the beginning of the row, the control signals selv<0> and selv<4> of the voltage source selection switch swv0 and the metal line short-circuit switch swv4 on the left are at a high level, control signals of other switches on the left are at a low level, the control signal seli<2> of the current source selection switch swi2 on the right is at a high level, and control signals of other switches on the right are at a low level. In this condition, the reference voltages before driving on the gates of the source follower transistors MSF meet a following equation,

V_{SF}<0>=V_{SF}<1>=V_{SF}<2>= . . . =V_{SF}<N−1>=Vcal−I*R_{swv0},

where I is an output current value of the current source, and R_{swv0} is on-resistance of the voltage source selection switch swv0.

After the analog-to-digital conversion of the reference signal is completed, the control signal selv<0> of the voltage source selection switch swv0 on the left becomes low, the control signal selv<1> of the voltage source selection switch swv1 on the left becomes high, and control signals of other switches on the left remain unchanged. The control signal seli<2> of the current source selection switch swi2 on the right becomes low, the control signal seli<3> of the current source selection switch swi3 on the right becomes high, and control signals of other switches on the right remain unchanged. In this condition, the reference voltages before driving on the gates of the source follower transistors MSF meet a following equation,

V_{SF}<0>=(Vcal−I*R_{swv1})

V_{SF}<1>=(Vcal−I*R_{swv1})−I*R

V_{SF}<2>=(Vcal−I*R_{swv})−2*I*R

. . .

V_{SF}<N−1>=(Vcal−I*R_{swv1)-(}N−1)*I*R,

where R_{swv1} is on-resistance of the voltage source selection switch swv1. R_{swv0} and R_{swv} may be the same. Compared with FIG. 3, a starting voltage of the reference signal before driving simulated by the calibration row with drive is reduced by I*R_{swv0}. The real effective reference voltages after driving obtained from left to right still start from 0, and are linearly input with an I*R*A interval, where A is a gain of the source follower transistor MSF. An overall deviation I*R_{swv0} of the starting voltage is isolated by a DC blocking capacitor in the row processing array, and does not affect the calibration of the nonlinear ADC.

After processing on the left to right change of the reference voltage before driving is completed, a row address remains unchanged, and the reference voltages before driving become to change from right to left. It is required that the right terminal of the calibration row 109′ with drive is connected to the voltage source 108 through switches, and the left terminal of the calibration row 109′ is connected to the current source 110 through switches. The method is similar as the above, except that the switches for turning on or off are opposite to the above embodiment, which is not repeated here.

That is, in one calibration row 109′ with drive, a plurality of selection switch groups are respectively arranged at a first terminal of the first and second metal lines, at a second terminal of the first and second metal lines, and between the first metal line and the second metal line, and an on-off state of the plurality of selection switch groups is controlled to achieve an alternation between two connection states. One connection state is that the left terminal of the calibration row 109′ with drive is connected to the voltage source 108 and the right terminal of the calibration row 109′ with drive is connected to the current source 110. The other connection state is that the right terminal of the calibration row 109′ with drive is connected to the voltage source 108 and the left terminal of the calibration row 109′ with drive is connected to the current source 110. In this manner, two conversion curves from left to right and from right to left are obtained respectively, which contain information about left-right differences. By performing digital processing on the two conversion curves, the influence of the left-right differences on the nonlinear ADC calibration can be eliminated.

In the above embodiments, for the sake of convenience, only 1 or 2 calibration rows with drive are provided in the reference voltage generating circuit 107. In practice, more rows may be used. More preferably, digital codes corresponding to the reference voltages after driving output from a same column of the plurality of calibration rows with drive are averaged to form a nonlinear-output curve, thereby eliminating influence of noises and improving calculation accuracy of the nonlinear ADC calibration parameters.

In addition, if the pixel unit array is too small, that is, the number N of columns being relatively small, the reference voltages generated by the nonlinear analog-to-digital converter calibration circuit may be too few, which is not conducive to the digital module to calculate accurate nonlinear calibration parameters subsequently. In this condition, two or more rows of calibration rows with drive may be connected to each other as a whole to simulate an entire image output range, which is used to provide a reference voltage before driving and output a reference voltage after driving.

As illustrated in FIG. 11, two rows 109a and 109b connected to each other as a whole 109 is adopted for simulation. Compared with FIG. 3, differences lie in that the first metal line and the second metal line of the two rows are connected separately as a whole, and the entire calibration range needs two rows of time to process. The first row performs analog-to-digital conversion of a first half of the reference voltage, and the second row performs analog-to-digital conversion of a latter half of the reference voltage. After processing of the two rows, a complete linear-input and nonlinear-output curve is assembled at a digital end to obtain the calibration parameters of the nonlinear analog-to-digital conversion circuit. The working principle and timing of the calibration circuit are the same as the aforementioned embodiments, and are not repeated here.

It should be noted that a metal line resistance R′ (metal connection resistance in the dotted box in the figure) at a connection terminal between the two rows should have the same resistance as a metal resistance R in a pitch, otherwise nonlinearity may appear at a junction to affect the calibration.

Finally, the nonlinear ADC calibration method of the present disclosure may be performed periodically or based on a trigger mechanism to update changes in the nonlinear ADC calibration parameters caused by changes in working environment and working parameters in real time, thereby improving stability and precision of nonlinear ADC output. Taking an image sensor as an example, the nonlinear ADC calibration circuit may be set to refresh the calibration parameters once or multiple times at a fixed period, such as every frame or multiple frames, or refresh the calibration parameters once or multiple times when it is detected that changes in a working temperature or working parameters reach a preset threshold.

In summary, in the calibration method for the nonlinear analog-to-digital conversion circuit of the image sensor, and the reference voltage generating circuit thereof provided in the embodiments of the present disclosure, prior to or during normal operation of the nonlinear analog-to-digital conversion circuit of the image sensor, the nonlinear analog-to-digital conversion circuit of the image sensor is used to test multiple reference voltages generated by the reference voltage generating circuit to obtain calibration parameters of the nonlinear analog-to-digital conversion circuit of the image sensor that are used to calibrate an output value of the nonlinear analog-to-digital conversion circuit of the image sensor at normal operation. In this manner, changes in nonlinear ADC calibration parameters caused by changes in working environment and working parameters are updated in real time, thereby improving stability and precision of the nonlinear analog-to-digital conversion circuit of the image sensor.

It is obvious to those skilled in the art that the present disclosure is not limited to the details of the exemplary embodiments described above, and that the present disclosure can be implemented in other specific forms without departing from the spirit or essential features of the present disclosure. Therefore, in any case, the embodiments should be regarded as exemplary and non-restrictive. In addition, it is obvious that the word “including” does not exclude other elements and steps, and the wording “a” does not exclude the plural. Multiple elements stated in the device claim may also be implemented by one element. The words first, second, etc. are used to indicate names, and do not indicate any particular order.

What is claimed is:

1. A calibration method for a nonlinear analog-to-digital conversion circuit of an image sensor, comprising:
providing the nonlinear analog-to-digital conversion circuit of the image sensor;
providing a reference voltage generating circuit; and
prior to or during normal operation of the nonlinear analog-to-digital conversion circuit of the image sensor, using the nonlinear analog-to-digital conversion circuit of the image sensor to test multiple reference voltages generated by the reference voltage generating circuit to obtain calibration parameters of the nonlinear analog-to-digital conversion circuit of the image sensor, wherein the calibration parameters are used to calibrate an output value of the nonlinear analog-to-digital conversion circuit of the image sensor at normal operation, to improve stability and precision of the nonlinear analog-to-digital conversion circuit of the image sensor.

2. The method according to claim 1, wherein the reference voltage generating circuit comprises at least one calibration row with drive disposed inside or outside a pixel array of the image sensor, and a voltage source or a current source disposed outside the pixel array, wherein each of the at least one calibration row with drive comprises a resistor or capacitor module comprising resistors or capacitors connected in series, and a first terminal and a second terminal of the resistor or capacitor module are respectively connected to the voltage source or the current source outside the pixel array;
wherein said using the nonlinear analog-to-digital conversion circuit of the image sensor to test the multiple reference voltages generated by the reference voltage generating circuit comprises:
in response to one calibration row with drive being selected, the voltage source or the current source providing multiple reference voltages before driving through the resistor or capacitor module;
after being driven by the calibration row with drive, the nonlinear analog-to-digital conversion circuit of the image sensor performing analog-to-digital conversion on the multiple reference voltages after driving simultaneously;
removing an offset error introduced in the calibration row with drive by a driving circuit and the nonlinear analog-to-digital conversion circuit of the image sensor using a correlated double sampling method; and
obtaining the calibration parameters of the nonlinear analog-to-digital conversion circuit of the image sensor after a test.

3. The method according to claim 2, wherein each of the at least one calibration row with drive further comprises a plurality of calibration row units, each of the plurality of calibration row units at least comprises the driving circuit and a row selection circuit, the driving circuit is a source follower transistor or a unit gain driving circuit, and the row selection circuit is a row selection transistor or a row selection switch circuit.

4. The method according to claim 3, wherein a metal line is used to connect the plurality of calibration row units and serves as the resistors connected in series in the calibration row with drive, a first terminal of the metal line is connected to the voltage source, a second terminal of the metal line is connected to the current source, the voltage source generates a first reference voltage before driving, and a current controlled by the current source flows through the metal line to generate multiple subsequent reference voltages before driving.

5. The method according to claim 4, wherein in the calibration row with drive, gates of source follower transistors in a same row are connected to a first metal line, gates of the row selection transistors in the same row are connected to a same row control line, a first terminal of the first metal line is connected to the voltage source, and the second terminal of the first metal line is connected to the current source through a first selection switch;
wherein the voltage source generates the first reference voltage before driving, the current controlled by the current source flows through the first metal line to generate the multiple subsequent reference voltages before driving, the multiple subsequent reference voltages before driving are the same as the first reference voltage when the first selection switch is turned off, and the multiple subsequent reference voltages before driving are different from the first reference voltage when the first selection switch is turned on.

6. The method according to claim 5, wherein the gates of the source follower transistors are connected to the first metal line at equal intervals to make the different reference voltages before driving are voltages that change at equal intervals.

7. The method according to claim 5, wherein each of the at least one calibration row with drive further comprises a second metal line connected in parallel with the first metal line, a first terminal of the second metal line is connected to the voltage source, and a second terminal of the second metal line is connected to the current source through a second selection switch, wherein the second selection switch is turned on when the first selection switch is turned off, and the second selection switch is turned off when the first selection switch is turned on, to make loads of the voltage source be consistent with loads of the current source.

8. The method according to claim 7, wherein the at least one calibration row with drive comprises a plurality of calibration rows with drive, and a first arrangement and a second arrangement are alternately adopted in the plurality of calibration rows with drive, wherein in the first arrangement, a first terminal of the first and second metal lines is disposed at a left terminal of the calibration row with drive, and a second terminal of the first and second metal lines is disposed at a right terminal of the calibration row with drive; and in the second arrangement, the first terminal of the first and second metal lines is disposed at the right terminal of the calibration row with drive, and the second terminal of the first and second metal lines is disposed at the left terminal of the calibration row with drive.

9. The method according to claim 7, wherein in one of the at least one calibration row with drive, a plurality of selection switch groups are respectively arranged at a first terminal of the first and second metal lines, at a second terminal of the first and second metal lines, and between the first metal line and the second metal line, and an on-off state of the plurality of selection switch groups is controlled to achieve an alternation between following two connection states: a left terminal of the calibration row with drive being connected to the voltage source and the right terminal of the calibration row with drive being connected to the current source; or the right terminal of the calibration row with drive being connected to the voltage source and the left terminal of the calibration row with drive being connected to the current source.

10. (canceled)

11. The method according to claim 2, wherein the at least one calibration row with drive comprises a plurality of calibration rows with drive, and digital codes corresponding to the reference voltages after driving output from a same column of the plurality of calibration rows with drive are averaged to form a nonlinear output curve.

12. The method according to claim 2, wherein a reference voltage range after driving output from the at least one calibration row with drive is adjusted by adjusting a current of the current source.

13. The method according to claim 2, wherein the at least one calibration row with drive comprises a plurality of calibration rows with drive, and the plurality of calibration rows with drive are connected with one another as a whole to provide the reference voltages before driving and output the reference voltages after driving.

14. A reference voltage generating circuit for calibrating a nonlinear analog-to-digital conversion circuit of an image sensor, comprising:
at least one calibration row with drive disposed inside or outside a pixel array of the image sensor, and a voltage source or a current source disposed outside the pixel array, wherein each of the at least one calibration row with drive comprises a resistor or capacitor module comprising resistors or capacitors connected in series, and a first terminal and a second terminal of the resistor or capacitor module are respectively connected to the voltage source or the current source outside the pixel array;
wherein in response to one calibration row with drive being selected, the voltage source or the current source provides multiple reference voltages before driving through the resistor or capacitor module; after being driven by the calibration row with drive, the nonlinear analog-to-digital conversion circuit of the image sensor performs analog-to-digital conversion on the multiple reference voltages after driving simultaneously; an offset error introduced in the calibration row with drive by a driving circuit and the nonlinear analog-to-digital conversion circuit of the image sensor is removed using a correlated double sampling method; and calibration parameters of the nonlinear analog-to-digital conversion circuit of the image sensor are obtained after a test.

15. The reference voltage generating circuit according to claim 14, wherein each of the at least one calibration row with drive further comprises a plurality of calibration row units, each of the plurality of calibration row units at least comprises the driving circuit and a row selection circuit, the driving circuit is a source follower transistor or a unit gain driving circuit, and the row selection circuit is a row selection transistor or a row selection switch circuit.

16. The reference voltage generating circuit according to claim 15, wherein a metal line is used to connect the plurality of calibration row units and serves as the resistors connected in series in the calibration row with drive, a first terminal of the metal line is connected to the voltage source, a second terminal of the metal line is connected to the current source, the voltage source generates a first reference voltage before driving, and a current controlled by the current source flows through the metal line to generate multiple subsequent reference voltages before driving.

17. The reference voltage generating circuit according to claim 16, wherein in the calibration row with drive, gates of source follower transistors in a same row are connected to a first metal line, gates of the row selection transistors in the same row are connected to a same row control line, a first terminal of the first metal line is connected to the voltage source, and the second terminal of the first metal line is connected to the current source through a first selection switch.

18. The reference voltage generating circuit according to claim 17, wherein the gates of the source follower transistors are connected to the first metal line at equal intervals.

19. The reference voltage generating circuit according to claim 17, wherein each of the at least one calibration row with drive further comprises a second metal line connected in parallel with the first metal line, a first terminal of the second metal line is connected to the voltage source, and a second terminal of the second metal line is connected to the current source through a second selection switch.

20. The reference voltage generating circuit according to claim 19, wherein the at least one calibration row with drive comprises a plurality of calibration rows with drive, and a first arrangement and a second arrangement are alternately adopted in the plurality of calibration rows with drive, wherein in the first arrangement, a first terminal of the first and second metal lines is disposed at a left terminal of the calibration row with drive, and a second terminal of the first and second metal lines is disposed at a right terminal of the calibration row with drive; and in the second arrangement, the first terminal of the first and second metal lines is disposed at the right terminal of the calibration row with drive, and the second terminal of the first and second metal lines is disposed at the left terminal of the calibration row with drive.

21. The reference voltage generating circuit according to claim 19, wherein in one of the at least one calibration row with drive, a plurality of selection switch groups are respectively arranged at a first terminal of the first and second metal lines, at a second terminal of the first and second metal lines, and between the first metal line and the second metal line, and an on-off state of the plurality of selection switch groups is controlled to achieve an alternation between following two connection states: a left terminal of the calibration row with drive being connected to the voltage source and the right terminal of the calibration row with drive being connected to the current source; or the right terminal of the calibration row with drive being connected to the voltage source and the left terminal of the calibration row with drive being connected to the current source.

22. (canceled)

23. (canceled)

24. (canceled)
